(19) United States
(12) Patent Application Publication
(10) Pub. No.: US 2005/0093404 A1
(43) Pub. Date: May 5, 2005

(54) Mini communications center

(76) Inventor: Robert F. Donovan, Sunnyvale, CA (US)

Correspondence Address: Robert F. Donovan, 1775 Lamont Court, Sunnyvale, CA, 94087, US

(21) Appl. No.: 10/981,013

(22) Filed: Nov. 3, 2004

Related U.S. Application Data
(63) Continuation of application No. 10/694,325, filed on Oct. 27, 2003.

(51) Int. Cl. H05K 1/00; H01R 12/00; A47B 67/02

(52) U.S. Cl. 312/242

(57) ABSTRACT

A mini-communications center for paper and wired or wireless communications is mounted into or onto a wall. The center comprises a lockable box made out of wood, plastic or metal with a lid that can serve as a writing desk when folded out to a horizontal position supported by door stays.

### BACKGROUND

1. Field of the Invention

The invention relates to a housing for communications equipment with wired and wireless connections.

2. Background

The ever increasing need to communicate for personal reasons and for improved efficiency in business and working environments lead to the development of telegraph and telephone to using radiowaves and other forms of high-speed transmission like optical fiber transmission. The use of cell phones is widespread now with the progress in semiconductor technology and communication standards as well as the build-up of the cell infrastructure. While cell phones and car phones increase the efficiency of the mobile communications scene, they are not ubiquitous and there is still a need for means for storing electronically transmitted information on legible paper-based media. There seems to be an unfulfilled demand for small communications equipment in protective housing in out-of-the-way rough environments like manufacturing facilities, as well as in areas of privacy like bathrooms, where suddenly emerging ideas need to be stored, like an inventor intending to catch creative ideas.

### SUMMARY OF THE INVENTION

The invention relates a housing in-the-wall or on-the-wall for paper-based and for electronics-based communications with wire and wireless connections for its electronic communications and computer equipment.

### IN THE DRAWINGS

FIG. 1 depicts the housing

FIG. 2 illustrates the housing with typical equipment

FIG 3 shows a demonstration version of the housing.

### DESCRIPTION OF THE PREFERRED EMBODIMENT

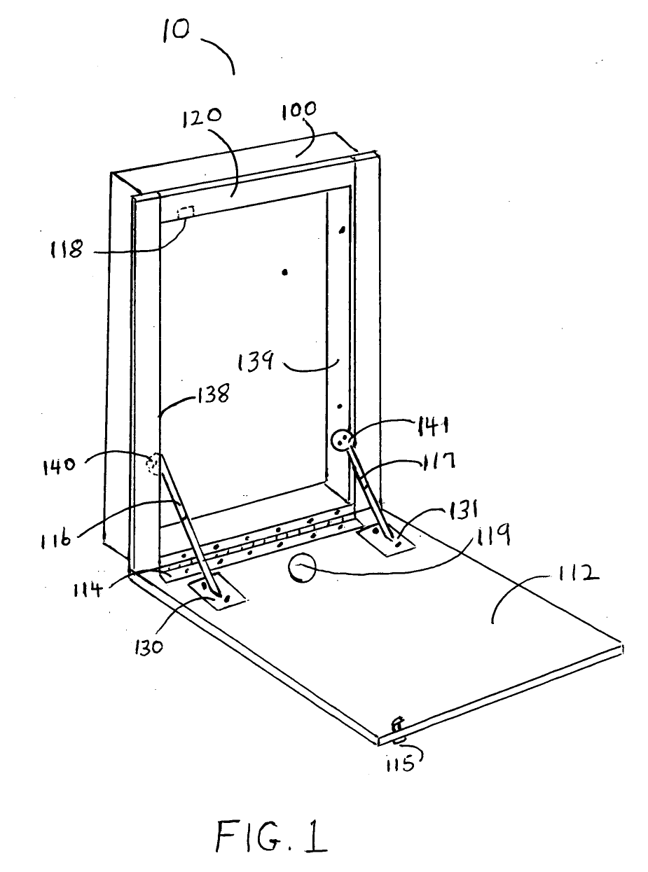

Many people have a need to communicate in unusual non-office environments with note-taking facilities highly desirable or even necessary. Manufacturing floors, machine shops, car service facilities want communication means close by oily machinery, sports facilities, medical facilities, bath rooms in residences and offices come to mind for convenient and out-of-the-way placement of communication equipment. The present invention proposes a wall-based mini communications center in a housing like a box with a fold-out, pull-down lid that in its horizontal position serves as a mini desk for activities like note taking etc. This wall box, made out of wood, metal or plastic, may contain physical storage for mini-equipment as follows:
a. provisions for paper-based data entry and storage equipment (note pad, rolodex for contact info etc.), as well as data entry instruments (e.g. pens, pencils).
b. provisions for attachment/storage facilities and connections (CAT5 cable) for wired communications via RJ45 (voice and data) utilizing present and emerging future technologies (like CallerID, Voice over the Internet), for later processing and for data storage (phone, notebook computer, Personal Digital Assistant (PDA), calculator, keyboard for remote computer/Internet access, magnetic/optical recorders, voice-activated dictaphone, music player (e.g. iPod), wireless access points for present and future wireless standards (Zigbee, BlueTooth etc.) and provisions for optional power outlet, battery charger etc.
c. a sturdy fold-out, pull-down lid for serving as a mini desk in a horizontal position.
d. Provisions for environmental considerations, e.g. waterproof design for outdoor and bathroom installation, decorative design for office and residential locations.
   The invention basically comprises a mini communications center 10, mounted into a wall between two studs or onto a wall. FIG. 1 gives an overview of an embodiment for mounting between studs a standard 16″ apart. A housing 100 shaped like a flat vertical box has a rectangular frame with a depth of about 4″ depth, a height of about 20″ and a width of about 13″. At its low end a lid 112 of about 20″ height and about 15″ width is attached to housing 100 via a hinge 114 (a piano hinge or a stripe of flexible plastic) by screws. The lid 112 can be pulled out by lock-handle 115 and folded about hinge 114 to a horizontal position secured by door stays 116 and 117 which slide upwards into the box 100 when the lid 112 is closed. In its horizontal position lid 112 forms a desk for writing and a a support for a laptop or notebook computer or a computer keyboard. Door stays 116 and 117 are fastened at one end to the lid 112 by hinge pads 130 and 131, pivoting around its horizontal axes. At the other end door stays 116 and 117 are fastened to the sidewalls 138 and 139 of the box 100 by fastener plates 140 and 141. Lock-handle 115 is adapted to engage a slotted stricke plate 118 in the underside of header frame 120. In order to make a telephone ring audible to the outside a hole 119, of about 5 cm (2″) diameter and covered by a mesh-screen, serves as an acoustical outlet. It is preferably located between the hinge mounting plates 130 and 131.

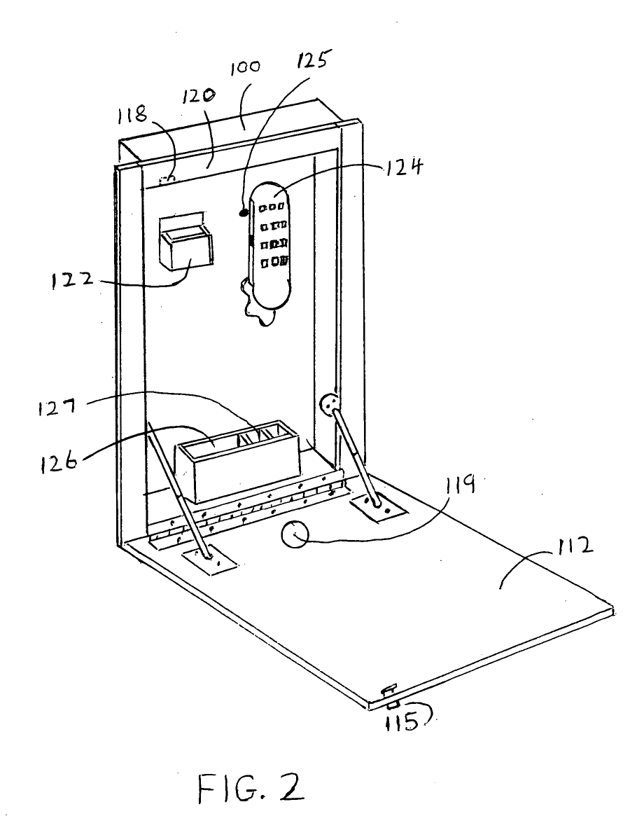

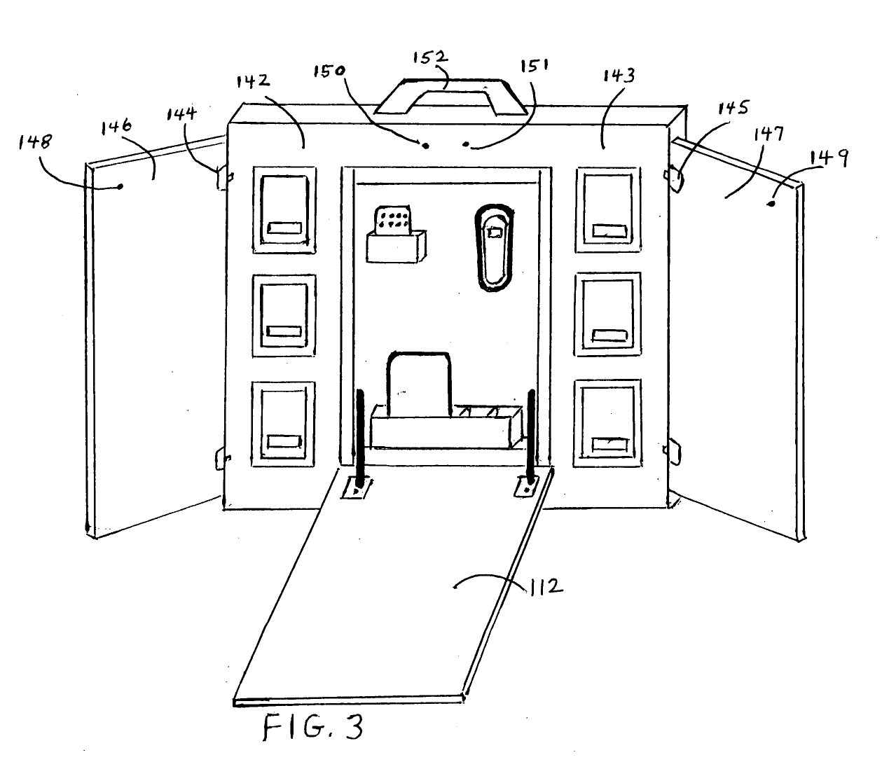

FIG. 2 shows the contents of housing 100. Attached to the backwall 121 of the housing 100 is calculator/PDA holder 122 and a telephone holder 124. with its connection (a CAT5 cable) emerging from connection hole 125. Connection hole 125 is also an outlet for a CAT5 or coax cable connection to a wireless access point like a transmitting/receiving antenna for Bluetooth. (not shown) for a wireless data network. The bottom of the box 100 holds a pocket 126 for a note pad and a dual pocket 127 for pens and pencils. In the lid-closed position there is enough space for a notebook computer. Lid handle can be a twist lock 119 with its strike plate 118 in the upper frame part 120 of housing 100. FIG. 3 shows another embodiment meant for sales demonstrations rather than actual installation. The housing 100, including vertical lid 112, is flanked on both sides by narrow panels 142 and 143 carrying displays of decorative housing finishes as options for the buyer. At the outer edges of panels 142, 143 are attached vertical hinges 144, 145, whose other sides are affixed to the outer edges of double doors 146 and 147. These doors are equipped with fingergrooves and fittings 148, 149 to engage rotor catches 150, 151 to hold the doors closed when appropriate. At the top of the box is a handle 152 for convenient carrying. Panels 160 demonstrate optional housing finishes for the customer's selection.

1. A mini-communications center in an open box, comprising
a. means for data entry and storage;
b. connections and holders for communication means;
c. a sturdy lid for the box, adapted to serve as a pull-down writing and support desk.

2. The communications center of claim 1 being wall-based

3. The communications center of claim 1, where the lid is adapted to serve as a pull-down writing and support desk.

4. An open wall box serving as mini communications c enter, comprising
a) physical storage facilities for a paper-based data entry and storage equipment;
b) physical storage facilities and connections for electronic communications and data processing equipment;
c) a sturdy lid for the box, rotably connected to the horizontal bottom frame part of the box and adapted to serve as a pull-down writing and support desk.

5. The wall box of claim 4 wherein
a lock on the lid and a strike plate on the housing adapted to lock the box.

6. An housing serving as demonstration mini communications center, comprising
a) physical storage facilities for a paper-based data entry and storage equipment;
b) physical storage facilities and connections for electronic communications and data processing equipment;
c) a sturdy lid for the box, adapted to serve as a pull-down writing and support desk.
d) side panels on both sides of the box for demonstrating optional finishes for the box and the lid;
e) a double door attached to the outside edge of the side panels adapted to cover the housing including the side panels; and
f) a central handle at the top of the box for convenient carrying.

7. A method for assembling a wall-based mini-communications center, comprising the steps of:
a) providing a suitably sized open box made out of a sturdy material;
b) providing a lid for the box;
c) providing a flexible hinge for mechanically connecting the lid to the box at the inside of their lower horizontal edges;
d) providing door stays to hold the folded-out lid in a horizontal position to serve as a mini-desk;
e) providing a wired connection for a telephone and a notebook computer on the backwall of the box;
f) providing pockets for a calculator, for a notepad and for writing instruments on the backwall; and
g) assembling the aforementioned components into the mini communications center.

8. The method of claim 5 further comprising the step of providing and assembling into the box at least one wireless access point.
